(19) United States
(12) Patent Application Publication
(10) Pub. No.: US 2021/0058094 A1
(43) Pub. Date: Feb. 25, 2021

(54) CODING AND DECODING OF COUPLED CHAINS

(71) Applicant: Nokia Technologies Oy, Espoo (FI)

(72) Inventors: Cyril MEASSON, Luxembourg (LU); Amira ALLOUM, Montrouge (FR); Keeth Saliya Jayasinghe LADDU, Espoo (FI)

(21) Appl. No.: 16/959,507

(22) PCT Filed: Jan. 15, 2018
(86) PCT No.: PCT/FI2018/050026

§ 371 Date: Jul. 1, 2020

(51) Int. Cl. H03M 13/11; H03M 13/09

(52) U.S. Cl. CPC H03M 13/1102; H03M 13/09

(57) ABSTRACT

Redundancy information is added to information to be sent over a medium and sent as spatially coupled chain with the redundancy information as local decision verification codes. In the receiving end, when the local decision verification code has been satisfied a preset number of times, a sliding window is shifted.

### TECHNICAL FIELD

Various example embodiments relates to communications.

### BACKGROUND

Wireless communication systems are under constant development. The need for faster communication and huge increase of the data amount create challenges for the communications systems. Use of spatially coupled codes is one alternative for future communications systems.

### BRIEF DESCRIPTION

According to an aspect, there is provided the subject matter of the independent claims. Some embodiments are defined in the dependent claims.

An aspect provides a method that comprises receiving, in a device, information to be sent over a medium; determining, by the device, redundancy information from a set of information symbols at the specific position; causing encoding, by the device, information symbols at the specific position and the redundancy information, to a spatially coupled chain; and causing, by the device, sending the information as the spatially coupled chain with the redundancy information as local decision verification codes.

Another aspect provides a method that comprises receiving, in a device, information to be sent over a medium; determining, by the device, at a specific position of the information, redundancy information as one or more local cyclic redundancy check codes at the specific position from a selection of neighboring symbols of symbols at the specific position; performing, by the device, cyclic redundancy check encoding to information comprising both the received information and the redundancy information by associating bits in the specific position with corresponding one or more local cyclic redundancy check codes; forming a spatially coupled chain by performing to the result of the cyclic redundancy check encoding spatially coupled low density parity check code encoding; and causing, by the device, sending the information as the spatially coupled chain with the redundancy information as local decision verification codes.

Another aspect provides a method that comprises receiving, in a device, information to be sent over a medium; determining, by the device, redundancy information as one or more local cyclic redundancy check codes at a specific position from a set of information symbols at the specific position; performing, by the device, a round of successive cyclic redundancy check encodings and/or by overlapping cyclic redundancy checks to information comprising both the received information the redundancy information by associating bits in the specific position with corresponding one or more local cyclic redundancy check codes; forming a spatially coupled chain by performing to the result of the cyclic redundancy check encoding spatially coupled low density parity check code encoding; and causing, by the device, sending the information as the spatially coupled chain with the redundancy information as local decision verification codes.

A still further aspect provides a method that comprises receiving, in a device, information to be sent over a medium; determining, by the device, redundancy information from a set of information symbols at a specific position by calculating, by the device, the redundancy information as one or more local cyclic redundancy check codes at the specific position according to one or more design parameters; performing, by the device, cyclic redundancy check encoding to information comprising both the received information and the redundancy information by inserting bits in the one or more local cyclic redundancy check codes so that the bits are inserted regularly in the received information; and causing obtaining, by the device, a spatially coupled chain by spatially coupling the result of the cyclic redundancy check encoding; and causing, by the device, sending the information as the spatially coupled chain with the redundancy information as local decision verification codes, wherein one or more design parameters of cyclic redundancy check codes are determined, by the device, according to at least one of characteristics of a waveform carrying the spatially coupled chain, a shape of the waveform, and expected characteristics of the medium channel.

Another aspect provides a method that comprises receiving, in a device, information to be sent over a medium; determining, by the device, at a specific position of the information, redundancy information from a selection of neighboring symbols of symbols at the specific position by calculating, by the device, the redundancy information as one or more local cyclic redundancy check codes at the specific position according to one or more design parameters; performing, by the device, cyclic redundancy check encoding to information comprising both the received information and the redundancy information by inserting bits in the one or more local cyclic redundancy check codes so that the bits are inserted regularly in the received information; obtaining, by the device, a spatially coupled chain by performing spatially coupled low density parity check code encoding, or by spatially coupled turbo code encoding or spatially coupled equalization to the result of the cyclic redundancy check encoding; and causing, by the device, sending the information as the spatially coupled chain with the redundancy information as local decision verification codes, wherein one or more design parameters of cyclic redundancy check codes are determined, by the device, according to at least one of characteristics of a waveform carrying the spatially coupled chain, a shape of the waveform, and expected characteristics of the medium channel.

An aspect provides a method comprising receiving, in a device, over a medium, a spatially coupled chain comprising redundancy information; decoding, by the device, the spatially coupled chain using a sliding window; determining from the decoded redundancy information whether or not a local decision verification code has been satisfied; if the local decision verification code has not been satisfied, repeating the decoding and the determining; if the local decision verification code has been satisfied, checking whether the local decision verification code has been satisfied a preset number of times; if the local decision verification code has not been satisfied the preset number of times, repeating the decoding and the determining; if the local decision verification code has been satisfied the preset number of times, shifting the sliding window and repeating the decoding and the determining.

An aspect provides a method comprising receiving, in a device, over a medium, a spatially coupled chain comprising redundancy information; decoding, by the device, the spatially coupled chain using a sliding window; determining from the decoded redundancy information whether or not a local decision verification code has been satisfied; if the local decision verification code has not been satisfied, repeating the decoding and the determining; if the local decision verification code has been satisfied, checking whether the local decision verification code has been satisfied a preset number of times; if the local decision verification code has not been satisfied the preset number of times, repeating the decoding and the determining; if the local decision verification code has been satisfied the preset number of times, shifting the sliding window and repeating the decoding and the determining, wherein a cyclic redundancy check code is used as the local decision verification code.

An aspect provides a device comprising means for receiving information to be sent over a medium; means for determining redundancy information from a set of information symbols at a specific position; means for encoding or causing encoding information symbols at the specific position and the redundancy information, to a spatially coupled chain; and means for causing, by the device, sending the information as the spatially coupled chain with the redundancy information as local decision verification codes.

Another aspect provides a device comprising means for performing any method disclosed above.

A further aspect provides a device comprising means for receiving information to be sent over a medium; means for determining redundancy information from a set of information symbols at a specific position by computing one or more local cyclic redundancy check codes at the specific position; means for performing cyclic redundancy check encoding to information comprising both the received information and the redundancy information by associating bits in the specific position with corresponding one or more local cyclic redundancy check codes; means for encoding or causing encoding information symbols at the specific position and the redundancy information, to a spatially coupled chain with means for forming the spatially coupled chain by performing to the result of the cyclic redundancy check encoding spatially coupled low density parity check code encoding; and means for causing, by the device, sending the information as the spatially coupled chain with the redundancy information as local decision verification codes.

A still further aspect provides a device comprising means for receiving information to be sent over a medium; means for determining one or more design parameters of cyclic redundancy check codes according to at least one of characteristics of a waveform carrying the spatially coupled chain, a shape of the waveform, and expected characteristics of the medium channel; means for determining redundancy information from a set of information symbols at a specific position; means for encoding or causing encoding information symbols at the specific position and the redundancy information, to a spatially coupled chain; and means for causing, by the device, sending the information as the spatially coupled chain with the redundancy information as local decision verification codes; wherein the means for determining redundancy information are configured to calculate the redundancy information as one or more local cyclic redundancy check codes at the specific position according to the one or more design parameters, and to perform or to cause perform cyclic redundancy check encoding to information comprising both the received information and the redundancy information by inserting bits in the one or more local cyclic redundancy check codes so that the bits are inserted regularly in the received information; and the means for causing sending the information as the spatially coupled chain means are configured to cause obtaining the spatially coupled chain by spatially coupling the result of the cyclic redundancy check encoding.

A yet further aspect provides a device comprising means for receiving over a medium a spatially coupled chain comprising redundancy information; means for decoding the spatially coupled chain using a sliding window; means for determining from the decoded redundancy information whether or not a local decision verification code has been satisfied; means for checking, in response to the local decision verification code being satisfied, whether the local decision verification code has been satisfied a preset number of times; means for causing, in response to the local decision verification code not being satisfied or not being satisfied the preset number of times, the means for decoding and the means for determining to repeat the decoding and the determining; and means for shifting, in response to the local decision verification code being satisfied the preset number of times, the sliding window.

Another aspect provides a device comprising means for receiving over a medium a spatially coupled chain comprising redundancy information; means for decoding the spatially coupled chain using a sliding window; means for determining from the decoded redundancy information whether or not a local decision verification code has been satisfied; means for checking, in response to the local decision verification code being satisfied, whether the local decision verification code has been satisfied a preset number of times; means for causing, in response to the local decision verification code not being satisfied or not being satisfied the preset number of times, the means for decoding and the means for determining to repeat the decoding and the determining; and means for shifting, in response to the local decision verification code being satisfied the preset number of times, the sliding window, wherein the device is configured to use a cyclic redundancy check code as the local decision verification code.

Still a further aspect provides a computer program comprising instructions for causing a device to perform at least the following: determining redundancy information from a set of information symbols at a specific position of received information that is to be sent over a medium; causing encoding information symbols at the specific position and the redundancy information, to a spatially coupled chain; and causing sending the information as the spatially coupled chain with the redundancy information as local decision verification codes.

Another aspect provides a computer program comprising instructions for causing a device to perform any method disclosed above.

An aspect provides a computer program comprising instructions for causing a device to perform at least the following: decoding a received spatially coupled chain comprising redundancy information using a sliding window; determining from the decoded redundancy information whether or not a local decision verification code has been satisfied; if the local decision verification code has not been satisfied, repeating the decoding and the determining; if the local decision verification code has been satisfied, checking whether the local decision verification code has been satisfied a preset number of times; if the local decision verification code has not been satisfied the preset number of times, repeating the decoding and the determining; and if the local decision verification code has been satisfied the preset number of times, shifting the sliding window and rep eating the decoding and the determining.

Another aspect provides a computer program comprising instructions for causing a device to perform at least the following: decoding a received spatially coupled chain comprising redundancy information using a sliding window; determining from the decoded redundancy information whether or not a local decision verification code has been satisfied; if the local decision verification code has not been satisfied, repeating the decoding and the determining; if the local decision verification code has been satisfied, checking whether the local decision verification code has been satisfied a preset number of times; if the local decision verification code has not been satisfied the preset number of times, repeating the decoding and the determining; and if the local decision verification code has been satisfied the preset number of times, shifting the sliding window and repeating the decoding and the determining, wherein a cyclic redundancy check code is used as the local decision verification code.

A further aspect provides a signal with embedded data, the signal being encoded in accordance with an encoding process in which information symbols at a specific position of received data and redundancy information determined from a set of information symbols at the specific position are encoded to a spatially coupled chain.

Another aspect provides an apparatus comprising at least one processor; and at least one memory including computer program code; the at least one memory and the computer program code configured to, with the at least one processor, cause the apparatus at least to perform: determining redundancy information from a set of information symbols at a specific position of received information that is to be sent over a medium; encoding or causing encoding information symbols at the specific position and the redundancy information to a spatially coupled chain; and causing sending the information as the spatially coupled chain with the redundancy information as local decision verification codes.

Yet another aspect provides an apparatus comprising at least one processor; and at least one memory including computer program code; the at least one memory and the computer program code configured to, with the at least one processor, cause the apparatus at least to perform: determining redundancy information from a set of information symbols at a specific position of received information that is to be sent over a medium by computing one or more local cyclic redundancy check codes at the specific position; performing cyclic redundancy check encoding to information comprising both the received information and the redundancy information by associating bits in the specific position with corresponding one or more local cyclic redundancy check codes; encoding or causing encoding information symbols at the specific position and the redundancy information to a spatially coupled chain by performing to the result of the cyclic redundancy check encoding spatially coupled low density parity check code encoding; and causing sending the information as the spatially coupled chain with the redundancy information as local decision verification codes.

Another aspect provides an apparatus comprising at least one processor; and at least one memory including computer program code; the at least one memory and the computer program code configured to, with the at least one processor, cause the apparatus at least to perform: determining one or more design parameters of cyclic redundancy check codes according to at least one of characteristics of a waveform carrying the spatially coupled chain, a shape of the waveform, and expected characteristics of the medium channel; determining redundancy information from a set of information symbols at a specific position of received information that is to be sent over a medium by calculating the redundancy information as one or more local cyclic redundancy check codes at the specific position according to the one or more design parameters; performing cyclic redundancy check encoding to information comprising both the received information and the redundancy information by inserting bits in the one or more local cyclic redundancy check codes so that the bits are inserted regularly in the received information; encoding or causing encoding information symbols at the specific position and the redundancy information to a spatially coupled chain by spatially coupling the result of the cyclic redundancy check encoding; and causing sending the information as the spatially coupled chain with the redundancy information as local decision verification codes.

Still a further aspect provides an apparatus comprising at least one processor; and at least one memory including computer program code; the at least one memory and the computer program code configured to, with the at least one processor, cause the apparatus at least to perform: decoding a received spatially coupled chain comprising redundancy information using a sliding window; determining from the decoded redundancy information whether or not a local decision verification code has been satisfied; if the local decision verification code has not been satisfied, repeating the decoding and the determining; if the local decision verification code has been satisfied, checking whether the local decision verification code has been satisfied a preset number of times; if the local decision verification code has not been satisfied the preset number of times, repeating the decoding and the determining; and if the local decision verification code has been satisfied the preset number of times, shifting the sliding window and repeating the decoding and the determining.

Still a further aspect provides an apparatus comprising at least one processor; and at least one memory including computer program code; the at least one memory and the computer program code configured to, with the at least one processor, cause the apparatus at least to perform: decoding a received spatially coupled chain comprising redundancy information using a sliding window; determining from the decoded redundancy information whether or not a local decision verification code has been satisfied; if the local decision verification code has not been satisfied, repeating the decoding and the determining; if the local decision verification code has been satisfied, checking whether the local decision verification code has been satisfied a preset number of times; if the local decision verification code has not been satisfied the preset number of times, repeating the decoding and the determining; and if the local decision verification code has been satisfied the preset number of times, shifting the sliding window and repeating the decoding and the determining; wherein the at least one memory and the computer program code are configured to, with the at least one processor, further cause the apparatus at least to use a cyclic redundancy check code as the local decision verification code.

Yet an aspect provides an apparatus comprising: an encoding circuitry configured at least to determine redundancy information from a set of information symbols at a specific position of received information that is to be sent over a medium and to encode information symbols at the specific position and the redundancy information to a spatially coupled chain; and a decoding circuitry configured at least to decode a received spatially coupled chain comprising redundancy information using a sliding window, to determine from the decoded redundancy information whether or not a local decision verification code has been satisfied, to repeat, in response to the local decision verification code not being satisfied, the decoding and the determining, to check, in response to the local decision verification code being satisfied, whether the local decision verification code has been satisfied a preset number of times; to repeat, in response to the local decision verification code not being satisfied the preset number of times, the decoding and the determining, and to shift, in response to the local decision verification code being satisfied the preset number of times, the sliding window and to repeat the decoding and the determining.

Another aspect provides an apparatus comprising: an encoding circuitry configured at least to determine redundancy information from a set of information symbols at a specific position of received information that is to be sent over a medium and to encode information symbols at the specific position and the redundancy information to a spatially coupled chain; and a decoding circuitry configured at least to decode a received spatially coupled chain comprising redundancy information using a sliding window, to determine from the decoded redundancy information whether or not a local decision verification code has been satisfied, to repeat, in response to the local decision verification code not being satisfied, the decoding and the determining, to check, in response to the local decision verification code being satisfied, whether the local decision verification code has been satisfied a preset number of times; to repeat, in response to the local decision verification code not being satisfied the preset number of times, the decoding and the determining, and to shift, in response to the local decision verification code being satisfied the preset number of times, the sliding window and to repeat the decoding and the determining; wherein the encoding circuitry and the decoding circuitry are further configured to use a cyclic redundancy check code as the local decision verification code and the encoding circuitry is further configured to determine the redundancy information by computing one or more local cyclic redundancy check codes at the specific position, to perform cyclic redundancy check encoding to information comprising both the received information and the redundancy information by associating bits in the specific position with corresponding one or more local cyclic redundancy check codes, and to form the spatially coupled chain by performing to the result of the cyclic redundancy check encoding spatially coupled low density parity check code encoding.

Still a further aspect provides an apparatus comprising: an encoding circuitry configured at least to determine redundancy information from a set of information symbols at a specific position of received information that is to be sent over a medium and to encode information symbols at the specific position and the redundancy information to a spatially coupled chain; and a decoding circuitry configured at least to decode a received spatially coupled chain comprising redundancy information using a sliding window, to determine from the decoded redundancy information whether or not a local decision verification code has been satisfied, to repeat, in response to the local decision verification code not being satisfied, the decoding and the determining, to check, in response to the local decision verification code being satisfied, whether the local decision verification code has been satisfied a preset number of times; to repeat, in response to the local decision verification code not being satisfied the preset number of times, the decoding and the determining, and to shift, in response to the local decision verification code being satisfied the preset number of times, the sliding window and to repeat the decoding and the determining. wherein the encoding circuitry and the decoding circuitry are further configured to use a cyclic redundancy check code as the local decision verification code and the encoding circuitry is further configured to determine one or more design parameters of cyclic redundancy check codes according to at least one of characteristics of a waveform carrying the spatially coupled chain, a shape of the waveform, and expected characteristics of the medium channel, calculate the redundancy information as one or more local cyclic redundancy check codes at the specific position according to the one or more design parameters, perform cyclic redundancy check encoding to information comprising both the received information and the redundancy information by inserting bits in the one or more local cyclic redundancy check codes so that the bits are inserted regularly in the received information; and cause obtaining, by the device, the spatially coupled chain by spatially coupling the result of the cyclic redundancy check encoding.

An aspect provides a non-transitory computer readable medium comprising program instructions for causing an apparatus to perform at least the following: determining redundancy information from a set of information symbols at a specific position of received information that is to be sent over a medium; encoding or causing encoding information symbols at the specific position and the redundancy information, to a spatially coupled chain; and causing sending the information as the spatially coupled chain with the redundancy information as local decision verification codes.

Another aspect provides a non-transitory computer readable medium comprising program instructions for causing an apparatus to perform at least the following: decoding a received spatially coupled chain comprising redundancy information using a sliding window; determining from the decoded redundancy information whether or not a local decision verification code has been satisfied; checking, in response to the local decision verification code being satisfied, whether the local decision verification code has been satisfied a preset number of times; causing, in response to the local decision verification code not being satisfied or not being satisfied the preset number of times, repeating the decoding and the determining; shifting, in response to the local decision verification code being satisfied the preset number of times, the sliding window and repeating the decoding and the determining.

Another aspect provides a non-transitory computer readable medium comprising program instructions stored thereon for performing at least the following: determining redundancy information from a set of information symbols at a specific position of received information that is to be sent over a medium; encoding or causing encoding information symbols at the specific position and the redundancy information to a spatially coupled chain; and causing sending the information as the spatially coupled chain with the redundancy information as local decision verification codes.

Still another aspect provides a non-transitory computer readable medium comprising program instructions stored thereon for performing at least the following: decoding a received spatially coupled chain comprising redundancy information using a sliding window; determining from the decoded redundancy information whether or not a local decision verification code has been satisfied; checking, in response to the local decision verification code being satisfied, whether the local decision verification code has been satisfied a preset number of times; causing, in response to the local decision verification code not being satisfied or not being satisfied the preset number of times, repeating the decoding and the determining; shifting, in response to the local decision verification code being satisfied the preset number of times, the sliding window and repeating the decoding and the determining.

One or more examples of implementations are set forth in more detail in the accompanying drawings and the description below. Other features will be apparent from the description and drawings, and from the claims.

### BRIEF DESCRIPTION OF DRAWINGS

In the following example embodiments will be described in greater detail with reference to the attached drawings, in which

FIGS. 1A and 1B illustrate exemplified wireless communication systems;

FIG. 2 shows an example of a spatially coupled sequence;

FIGS. 3 to 7 illustrate exemplified processes; and

FIG. 8 is a schematic block diagram.

### DETAILED DESCRIPTION OF SOME EMBODIMENTS

The following embodiments are only presented as examples. Although the specification may refer to “an”, “one”, or “some” embodiment(s) and/or example(s) in several locations of the text, this does not necessarily mean that each reference is made to the same embodiment(s) or example(s), or that a particular feature only applies to a single embodiment and/or example. Single features of different embodiments and/or examples may also be combined to provide other embodiments and/or examples.

Embodiments and examples described herein may be implemented in any communications system, wired, wireless and/or optical, that are configurable to support spatially coupled codes. In the following, different exemplifying embodiments will be described using, as an example of an access architecture to which the embodiments may be applied, a radio access architecture based on long term evolution advanced (LTE Advanced, LTE-A) or new radio (NR, 5G), without restricting the embodiments to such an architecture, however. It is obvious for a person skilled in the art that the embodiments may also be applied to other kinds of communications networks having suitable means by adjusting parameters and procedures appropriately. Some examples of other options for suitable systems are the universal mobile telecommunications system (UMTS) radio access network (UTRAN or E-UTRAN), long term evolution (LTE, the same as E-UTRA), beyond 5G, wireless local area network (WLAN or WiFi), worldwide interoperability for microwave access (WiMAX), Bluetooth®, personal communications services (PCS), ZigBee®, wideband code division multiple access (WCDMA), systems using ultra-wideband (UWB) technology, sensor networks, mobile ad-hoc networks (MANETs) and Internet Protocol multimedia subsystems (IMS) or any combination thereof.

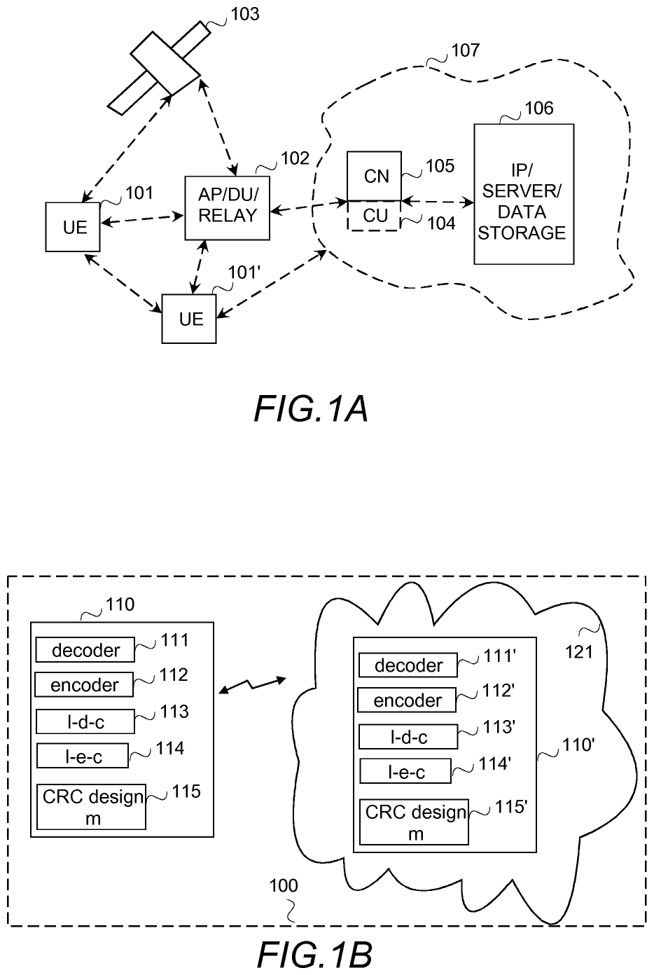

FIG. 1A depicts examples of simplified system architectures only showing some elements and functional entities, all being logical units, whose implementation may differ from what is shown. The connections shown in FIG. 1A are logical connections; the actual physical connections may be different. It is apparent to a person skilled in the art that the system typically comprises also other functions and structures than those shown in FIG. 1A.

The embodiments are not, however, restricted to the system given as an example but a person skilled in the art may apply the solution to other communication systems provided with necessary properties.

The example of FIG. 1A shows a part of an exemplifying radio access network.

FIG. 1A shows user devices 101 and 101′ configured to be in a wireless connection on one or more communication channels in a cell with an access node (such as (e/g)NodeB) 102 providing the cell. The physical link from a user device to a (e/g)NodeB is called uplink or reverse link and the physical link from the (e/g)NodeB to the user device is called downlink or forward link. It should be appreciated that (e/g)NodeBs or their functionalities may be implemented by using any node, host, server or access point etc. entity suitable for such a usage.

A communications system typically comprises more than one (e/g)NodeB in which case the (e/g)NodeBs may also be configured to communicate with one another over links, wired or wireless, designed for the purpose. These links may be used for signalling purposes. The (e/g)NodeB is a computing device configured to control the radio resources of communication system it is coupled to. The NodeB may also be referred to as a base station, an access point or any other type of interfacing device including a relay station capable of operating in a wireless environment. The (e/g)NodeB includes or is coupled to transceivers. From the transceivers of the (e/g)NodeB, a connection is provided to an antenna unit that establishes bi-directional radio links to user devices. The antenna unit may comprise a plurality of antennas or antenna elements. The (e/g)NodeB is further connected to core network 105 (CN or next generation core NGC). Depending on the system, the counterpart on the CN side can be a serving gateway (S-GW, routing and forwarding user data packets), packet data network gateway (P-GW), for providing connectivity of user devices (UEs) to external packet data networks, or mobile management entity (MME), etc.

The user device (also called UE, user equipment, user terminal, terminal device, etc.) illustrates one type of an apparatus to which resources on the air interface are allocated and assigned, and thus any feature described herein with a user device may be implemented with a corresponding apparatus, such as a relay node. An example of such a relay node is a layer 3 relay (self-backhauling relay) towards the base station.

The user device typically refers to a portable computing device that includes wireless mobile communication devices operating with or without a subscriber identification module (SIM), including, but not limited to, the following types of devices: a mobile station (mobile phone), smartphone, personal digital assistant (PDA), handset, device using a wireless modem (alarm or measurement device, etc.), laptop and/or touch screen computer, tablet, game console, notebook, and multimedia device. It should be appreciated that a user device may also be a nearly exclusive uplink only device, of which an example is a camera or video camera loading images or video clips to a network. A user device may also be a device having capability to operate in Internet of Things (IoT) network which is a scenario in which objects are provided with the ability to transfer data over a network without requiring human-to-human or human-to-computer interaction. The user device may also utilise cloud. In some applications, a user device may comprise a small portable device with radio parts (such as a watch, earphones or eyeglasses) and the computation is carried out in the cloud. The user device (or in some embodiments a layer 3 relay node) is configured to perform one or more of user equipment functionalities. The user device may also be called a subscriber unit, mobile station, remote terminal, access terminal, user terminal or user equipment (UE) just to mention but a few names or apparatuses.

Various techniques described herein may also be applied to a cyber-physical system (CPS) (a system of collaborating computational elements controlling physical entities). CPS may enable the implementation and exploitation of massive amounts of interconnected ICT devices (sensors, actuators, processors microcontrollers, etc.) embedded in physical objects at different locations. Mobile cyber physical systems, in which the physical system in question has inherent mobility, are a subcategory of cyber-physical systems. Examples of mobile physical systems include mobile robotics and electronics transported by humans or animals.

Additionally, although the apparatuses have been depicted as single entities, different units, processors and/or memory units (not all shown in FIG. 1A) may be implemented.

5G enables using multiple input-multiple output (MIMO) antennas, many more base stations or nodes or corresponding network devices than the LTE (a so-called small cell concept), including macro sites operating in co-operation with smaller stations and employing a variety of radio technologies depending on service needs, use cases and/or spectrum available. 5G mobile communications supports a wide range of use cases and related applications including video streaming, augmented reality, different ways of data sharing and various forms of machine type applications (such as (massive) machine-type communications (mMTC), including vehicular safety, different sensors and real-time control. 5G is expected to have multiple radio interfaces, namely below 6 GHz, cmWave and mmWave, and also being integradable with existing legacy radio access technologies, such as the LTE. Integration with the LTE may be implemented, at least in the early phase, as a system, where macro coverage is provided by the LTE and 5G radio interface access comes from small cells by aggregation to the LTE. In other words, 5G is planned to support both inter-RAT operability (such as LTE-5G) and inter-RI operability (inter-radio interface operability, such as below 6 GHz-cmWave, below 6 GHz-cmWave-mmWave). One of the concepts considered to be used in 5G networks is network slicing in which multiple independent and dedicated virtual sub-networks (network instances) may be created within the same infrastructure to run services that have different requirements on latency, reliability, throughput and mobility.

The current architecture in LTE networks is fully distributed in the radio and fully centralized in the core network. The low latency applications and services in 5G require to bring the content close to the radio which leads to local break out and multi-access edge computing (MEC). 5G enables analytics and knowledge generation to occur at the source of the data. This approach requires leveraging resources that may not be continuously connected to a network such as laptops, smartphones, tablets and sensors. MEC provides a distributed computing environment for application and service hosting. It also has the ability to store and process content in close proximity to cellular subscribers for faster response time. Edge computing covers a wide range of technologies such as wireless sensor networks, mobile data acquisition, mobile signature analysis, cooperative distributed peer-to-peer ad hoc networking and processing also classifiable as local cloud/fog computing and grid/mesh computing, dew computing, mobile edge computing, cloudlet, distributed data storage and retrieval, autonomic self-healing networks, remote cloud services, augmented and virtual reality, data caching, Internet of Things (massive connectivity and/or latency critical), critical communications (autonomous vehicles, traffic safety, real-time analytics, time-critical control, healthcare applications).

The communication system is also able to communicate with other networks, such as a public switched telephone network or the Internet 106, or utilise services provided by them. The communication network may also be able to support the usage of cloud services, for example at least part of core network operations may be carried out as a cloud service (this is depicted in FIG. 1A by “cloud” 107). The communication system may also comprise a central control entity, or a like, providing facilities for networks of different operators to cooperate for example in spectrum sharing.

Edge cloud may be brought into radio access network (RAN) by utilizing network function virtualization (NVF) and software defined networking (SDN). Using edge cloud may mean access node operations to be carried out, at least partly, in a server, host or node operationally coupled to a remote radio head or base station comprising radio parts. It is also possible that node operations will be distributed among a plurality of servers, nodes or hosts. Application of cloudRAN architecture enables RAN real time functions being carried out at the RAN side (in a distributed unit, DU 102) and non-real time functions being carried out in a centralized manner (in a centralized unit, CU 104).

It should also be understood that the distribution of labour between core network operations and base station operations may differ from that of the LTE or even be non-existent. Some other technology advancements probably to be used are Big Data and all-IP, which may change the way networks are being constructed and managed. 5G (or new radio, NR) networks are being designed to support multiple hierarchies, where MEC servers can be placed between the core and the base station or nodeB (gNB). It should be appreciated that MEC can be applied in 4G networks as well.

5G may also utilize satellite communication to enhance or complement the coverage of 5G service, for example by providing backhauling. Possible use cases are providing service continuity for machine-to-machine (M2M) or Internet of Things (IoT) devices or for passengers on board of vehicles, or ensuring service availability for critical communications, and future railway/maritime/aeronautical communications. Satellite communication may utilise geostationary earth orbit (GEO) satellite systems, but also low earth orbit (LEO) satellite systems, in particular mega-constellations (systems in which hundreds of (nano) satellites are deployed). Each satellite 103 in the mega-constellation may cover several satellite-enabled network entities that create on-ground cells. The on-ground cells may be created through an on-ground relay node 102 or by a gNB located on-ground or in a satellite.

It is obvious for a person skilled in the art that the depicted system is only an example of a part of a radio access system and in practice, the system may comprise a plurality of (e/g)NodeBs, the user device may have an access to a plurality of radio cells and the system may comprise also other apparatuses, such as physical layer relay nodes or other network elements, etc. At least one of the (e/g)NodeBs or may be a Home (e/g)nodeB. Additionally, in a geographical area of a radio communication system a plurality of different kinds of radio cells as well as a plurality of radio cells may be provided. Radio cells may be macro cells (or umbrella cells) which are large cells, usually having a diameter of up to tens of kilometers, or smaller cells such as micro-, femto- or picocells. The (e/g)NodeBs of FIG. 1A may provide any kind of these cells. A cellular radio system may be implemented as a multilayer network including several kinds of cells. Typically, in multilayer networks, one access node provides one kind of a cell or cells, and thus a plurality of (e/g)NodeBs are required to provide such a network structure.

For fulfilling the need for improving the deployment and performance of communication systems, the concept of “plug-and-play” (e/g)NodeBs has been introduced. Typically, a network which is able to use “plug-and-play” (e/g)Node Bs, includes, in addition to Home (e/g)NodeBs (H(e/g)nodeBs), a home node B gateway, or HNB-GW (not shown in FIG. 1A). A HNB Gateway (HNB-GW), which is typically installed within an operator's network may aggregate traffic from a large number of HNBs back to a core network.

Another way to depict an exemplary system is illustrated in FIG. 1B. FIG. 1B is a simplified system architecture only showing some elements and functional entities, all being logical units whose implementation may differ from what is shown. It is apparent to a person skilled in the art that the system may comprise any number of the illustrated elements and functional entities.

Referring to FIG. 1B, the system 100 comprises a plurality of devices 110, 110′ (only two shown in FIG. 1B) that may communicate with each other over one or more networks 121 and/or within a network. As said above, the networks or some of them may be wired, wireless, as illustrated in FIG. 1B, or optical.

One 110 of the devices illustrated in FIG. 1B depicts an end terminal of communications, whereas the other one depicts a network node 110′. The end terminal 110 may be a portable computing device (equipment, apparatus), and it may also be referred to as a user device, examples of which are given above with FIG. 1A. The network node 110′ may be any kind of a computing device, or network device, providing a connection point for transmissions on a communications network (access network and/or core network) and that can function as a redistribution point or an endpoint. There are plurality of network nodes of different types. An example of such network nodes is a base station, such as an evolved NodeB (eNB), providing a wide area, medium range or local area coverage for user terminals, for example. Other examples include gateways, servers, routers, switching network nodes.

The devices 110, 110′ are configured to support local decision-aided control for encoding and decoding. For that purpose each of the devices 110, 110′ comprises, for a decoder 111, 111′ a local decoder controlling unit (l-d-c) 113, 113′, and for an encoder 112, 112′ a local encoder controlling unit (l-e-c) 114, 114′, as separate units or integrated together, and in a memory 115 there are one or more cyclic redundancy check (CRC) designs, and one or more values for “m”. The CRC designs may comprise one or more design parameters for the CRC. The one or more values for “m” are for locally adjusting the amount of iterations during decoding, as will be explained in detail below. The one or more values for “m” may be set during network planning, delivered via an operation and maintenance subsystem, or be adjusted locally. The value of “m” may depend on a sliding window size and/or a coupling window size, and/or a lifting depth of spatially coupled codes.

Although in the example of FIG. 1B the devices 110, 110′ comprises both the local decoder controlling unit and the local encoder controlling unit it should be appreciated that even devices comprising only the local decoder controller unit provide some advantages will be achieved, as will be evident from the below examples.

In the below examples a spatially coupled chain is used, or more precisely a spatially coupled chain coded by Low Density Parity Check (LDPC) coding without restricting the examples to such a solution. It should be appreciated that the spatially coupled chain may be obtained using any suitable coding, such as spatially coupled turbo codes or spatially coupled equalization.

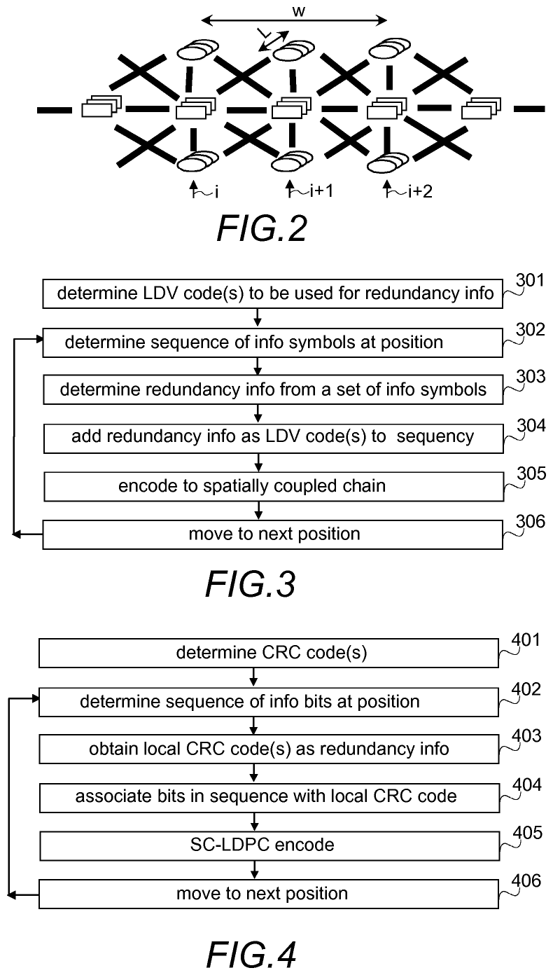

FIG. 2 illustrates an example of a sequence of a spatially coupled chain. A spatially coupled chain is a particular sequence of bits or symbols that are locally correlated in a regular spatial manner or in an irregular spatial manner. In the illustrated example of FIG. 2, there is a regular spatially coupled code with a lifting depth L and a symmetric coupling window size w. In the illustrated example, the value of L is three and the value of w is three. A node (illustrated by a rectangle) locating at position “i” is connected to two check nodes (illustrated by ellipses) at positions “i+1” and “i+2”. For the illustrated example, following formula (1) may be used:

N=L P nₚᵣₒₜₒ₋ₚₒₛᵢₜᵢₒₙ+L n₀ (1)

wherein

N=total number of bits of the spatially coupled chain coded by LDPC

L=lifting depth

P=total number of proto-positions=chain length

nₚᵣₒₜₒ₋ₚₒₛᵢₜᵢₒₙ=number of bits at a given position (2 in the example)

n₀=termination bits associated with a rate loss

In FIGS. 3 to 6 different examples of how the local encoder controlling unit with an encoder, or any corresponding unit, including an encoder circuitry if implemented without controlling unit, may be configured to perform encoding of information using an encoding scheme that speeds up decoding of the information. FIGS. 3 to 5 illustrate examples in which the encoding is performed by one device (entity) and FIG. 6 an example in which the encoding is performed by two devices (entities). In the illustrated encoding schemes, decision verification codes are added as redundancy information to an encoded signal, or to a signal to be encoded, so that the decoder can use the decision verification codes to determine when to end decoding, as will be described in more detail below with FIG. 7. In the illustrated examples local CRC codes are used as an example of decision verification codes without restricting the examples to the local CRC codes. For example, any of Bose-Chaudhuri-Hocquenghem (BCH) codes may be used instead. The decision verification codes differ from traditional error detection and correction codes in that sense that they are dedicated for acceleration of the decoding processing, even though they may also provide the error detection and correction. Although not explicitly mentioned in FIGS. 3 to 6, the end result is an encoded communication signal that will be sent as a propagation wave over a medium that may be a storage, a wireless medium or wired medium, such as optical fiber.

Referring to FIG. 3, one or more local decision verification (LDV) codes to be used for redundancy information are determined in block 301. For example, a length of a code to be added as redundancy information may be determined, or a selection of a code/codes to be used is performed thereby also determining the length, or the length determines the code to be used. The length may be tailored according to the coupling parameters currently in use. For example, the length may be equal to the lifting size used, a multiple of the lifting size used, or a fraction of the lifting size used. For example, if the lifting size is 3, the length may be 3, 6, or 1, just to list a couple of examples. Then the sequence of information symbols to be encoded is determined in block 302 at the current proto-position, and redundancy information is determined in block 303 from a set of information symbols, for example from a set of neighboring symbols of the determined information symbols. In other words, some, typically neighboring, of information symbols at the specific position, are selected, and the redundancy information is then determined or computed using/based on the selected set of (neighboring) information symbols. The number of selected (neighboring) symbols is determined in the example by means of the length of the code to be added as redundancy information. The neighboring symbols, i.e. information symbols in the set, may be binary symbols but other symbols may be used as well.

Then the redundancy information, is added in block 304 to the sequence of the information symbols determined in block 302 as local decision verification code(s), and then the information symbols with the added redundancy information is encoded in block 305 to a spatially encoded chain that has the redundancy information as the local decision verification code(s). Then, although not shown in FIG. 3, causing sending the spatially encoded chain may take place, while the process moves, as long as there are information to be sent, in block 306 to a next proto-position, and the process continues from block 302 in the illustrated example.

In another implementation, in which the coupling parameter(s) according to which the length is determined, may vary at different proto-positions, the process proceeds from block 306 to block 301 to determine the local decision verification code(s) for the proto-position in question. In still another example, a preset fixed local decision verification code(s) may be used, in which case in block 301 the local decision verification code(s) may be obtained from the memory, or block 301 is omitted.

Referring to FIG. 4, one or more local cyclic redundancy check (CRC) codes to be used for redundancy information are determined in block 401. For example, a length of a code to be added as redundancy information may be determined, or a selection of a CRC code/codes to be used is performed thereby also determining the length, or the length determines the CRC code to be used, as described above with FIG. 3. Then the sequence of information symbols to be encoded is determined in block 402 at the current proto-position. At the proto-position determined in block 402, local CRC code is (local CRC codes are) obtained (determined) in block 403 from a linear codes, such as CRC circuits. For example, assuming that there is 2048 bits at a proto-position, CRC-8/32/64 can be associated as the local CRC code to those 2048 bits. The associated local CRC may be used at several stage of the decoding throughout the iteration to notify whether the 2048 coded bits are correctly decoded or not as a syndrome function. Another alternative is to use 8 CRC-8/32/64 each as the local CRC over 256 bits. The obtained local CRC code has the length defined by a design of the CRC code determined in block 401. Then in block 404 a number of bits R, calculated using following formula (2), are associated, at the proto-position, with the local CRC code obtained in block 403.

R=L nₚᵣₒₜₒ₋ₚₒₛᵢₜᵢₒₙ (2)

wherein

R=the number of bits associated

L=lifting depth

nₚᵣₒₜₒ₋ₚₒₛᵢₜᵢₒₙ=number of bits at the proto-position

By associating the bits with the local CRC code, CRC encoding is performed at block 404. The CRC encoding scheme may be a round of successive CRC encodings, producing R bits according to the formula (2) above at each round. Variations of the CRC encoding scheme, such as overlapping CRC, may be performed, as long as the variations also rely on a matching with a corresponding spatially coupled LDPC proto-positions. The thus formed new sequence of bits, is encoded in block 405 by spatially coupled LDPC to a corresponding chain, and the encoding process moves, as long as there are information to be sent, in block 406 to a next proto-position, and the process continues from block 402.

In another implementation, in which the coupling parameter(s) according to which the length is determined, may vary at different proto-positions, the process proceeds from block 406 to block 401 to determine the CRC code(s) for the proto-position in question.

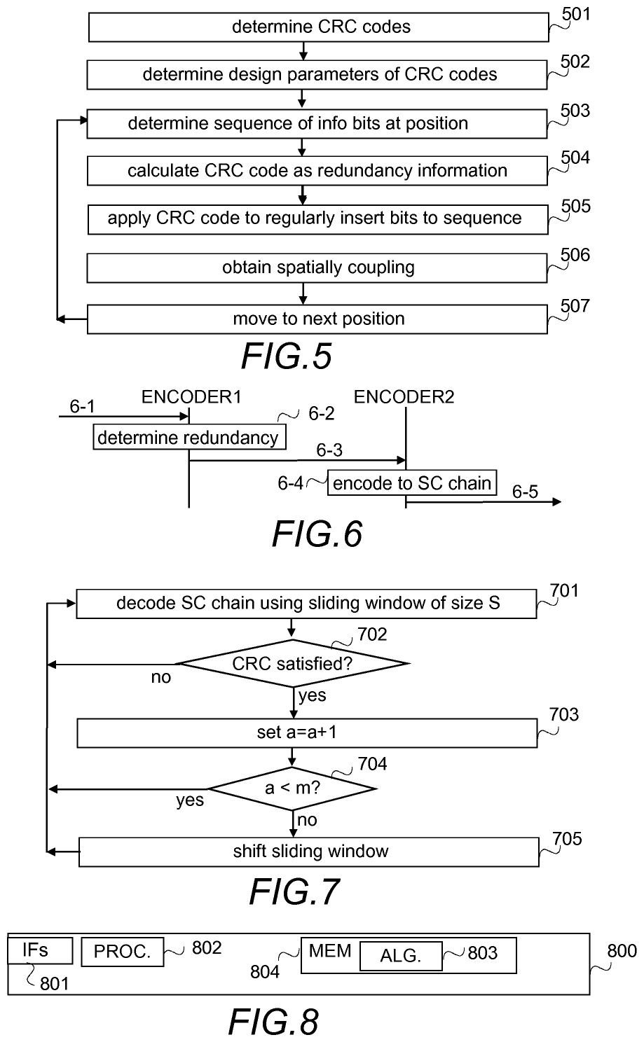

The example of FIG. 5 relates to a situation in which a sequence of information bits, is encoded and/or modulated and/or mapped to a communication waveform that may include pilots or additional headers.

Referring to FIG. 5, one or more local cyclic redundancy check (CRC) codes to be used for redundancy information are determined in block 501, as described above with FIG. 4. Design parameters, such as polynomial of CRC codes, redundancy length of the CRC codes and position of the CRC redundancy among the information sequence, of CRC codes are also determined (block 502). By determining one or more of the design parameters of the CRC codes the CRC codes may be tailored according to the communication waveform. For example, characteristics and/or the shape of the emitted waveform and/or expected channel characteristics may be taken into account when the one or more of the design parameters are determined. Examples of the characteristics of the emitted waveform that can tailor the design parameters include CRC redundancy information size, error-correcting code and pilot structure. Example of the shape of the emitted waveform that can tailor the design parameters include a size of fast Fourier transform (FFT) when Orthogonal Frequency Division Multiplexing is used, and a modulation format. The design parameter of the CRC code may result to the CRC code being a sequence of overlapping, potentially causal, CRC codes.

Then the sequence of information bits to be encoded is determined in block 503 at the current proto-position, and a CRC code is calculated in block 504 using the design parameters defined in block 502. The calculated CRC code is then applied in block 505 to the sequence of the information bits determined in block 503 in such a way that the bits in the calculated CRC code are regularly inserted in the sequence of the information bits. In other words, CRC encoding is performed at block 505. Then spatially coupling of the encoded sequence is obtained in block 506, for example by LDPC coupling, or by spatially coupled turbo codes, or by spatially coupled equalization. The encoding process moves, as long as there are information to be sent, in block 507 to a next proto-position, and the process continues from block 503.

The encoding is not necessarily performed by one entity, but two separate entities, or devices may perform the process. FIG. 6 illustrates an example of such a solution, in which encoders are used as examples of such solutions.

Referring to FIG. 6, information to be sent over a medium is received in an encoder1 (message 6-1) and the encoder1 determines in point 6-2 the redundancy information, for example using any of the described ways. Then encoding to a spatially encoded chain is caused by sending (message 6-3) from the encoder1 to an encoder2 the received information and the determined redundancy information. The encoder2 then encodes in point 6-4 the received information with the redundancy information to a spatially coupled chain, which is then forwarded/sent (message 6-5). In other words, in the example of FIG. 6, the encoder2 performs block 305, or block 405, or block 506 while the encoder1 performs other blocks in FIG. 3, or FIG. 4, or FIG. 5, correspondingly.

In FIG. 7 an example of how the local decoder controlling unit with a decoder, or any corresponding unit, including a decoder circuitry if implemented without a controlling unit, may be configured decode a spatially coupled chain. In the example of FIG. 7 it is assumed that a spatially coupled chain of information containing also redundancy information that can be used as decision verification codes is received. The spatially coupled chain may have been encoded according to one of the examples described above. An advantage of using one of the examples illustrated in FIGS. 3 to 5 is that it helps the decoder to capture an average displacement, and thereby speeds up the procedure. However, it should be appreciated that any other encoding scheme may be used. Further, the decoding party and the encoding party may have agreed beforehand what encoding scheme will be used thereby fastening the process compared to a situation in which the decoding party determines from the received chain the encoding scheme. Still a further possibility is that the system, and thereby the parties are configured to use only one scheme.

Referring to FIG. 7, when a spatially coded chain is decoded in block 701, using a sliding window of size S, it is checked in block 702, whether or not the decision verification code, which in the example is CRC, is satisfied. The size of the sliding window bears no significance to the invention, and any size, constant or a variable, for example a function of parameters, such as the coupling window and/or the lifting depth used in encoding, may be used.

If the verification code, i.e. CRC, is satisfied (block 702: yes), a value of variable “a” is incremented in block 703 by one and then the value of the variable “a” is compared with the value of “m”, i.e. with the value given locally to a number “m” of satisfied CRCs (decision verification codes) to end iterations of decoding. If the variable “a” is equal to “m” (block 704: no), the decoding of the chain is ended, the sliding window is shifted in block 705 by one or more positions, and the value of “a” is reset to zero. The number of positions the sliding window is shifted may a constant number, or depend on the sliding window size, and/or from the number “m”, for example. Then the process returns to block 701 to decode the chain, as long as there is chain to decode.

If the variable “a” is less than “m” (block 704: yes), or if the CRC is not satisfied (block 702: no), the process returns to block 701 to decode the chain, as long as there is chain to decode.

By maintaining information how many times CRC is satisfied, and stopping the decoding of the chain when the CRC is satisfied required times, it is possible to locally react to changes in the network during propagation: when the transmission channel quality is good, the decoding will take less iteration rounds thereby accelerating the sliding window decoding, whereas a bad transmission channel quality causes more iteration rounds. Since in prior art solutions the number of iteration rounds is set based on the worst case scenario, the disclosed decoding scheme with adaptive number of iterations results in lower average decoding latency, and better energy efficiency, especially with multi-edge coupled chains, without sacrificing the quality. When the disclosed decoding scheme is combined with a disclosed encoding scheme, the latency will be even smaller, and hence the energy efficiency even better.

The above described local encoding/decoding may be implemented in any layer, for example in a physical layer, or medium access control (MAC) layer, or application layer. As is evident from the above, the local control of encoding/decoding can be used for layers employing rather large block lengths (up to hundreds of kilobits), such as those utilizing very large scale integration, and for layers employing smaller block lengths.

The blocks, related functions, and information exchanges described above by means of FIGS. 3 to 7 are in no absolute chronological order, and some of them may be performed simultaneously or in an order differing from the given one. Naturally similar processes for several chains, or for one chain that is split, may run in parallel. Other functions can also be executed between them or within them, and other information may be sent. Some of the blocks or part of the blocks or one or more pieces of information can also be left out or replaced by a corresponding block or part of the block or one or more pieces of information.

The techniques and methods described herein may be implemented by various means so that an apparatus/device configured to support encoding and/or decoding mechanism based on at least partly on what is disclosed above with any of FIGS. 1A to 7, including implementing one or more functions/operations of a corresponding device (network node or terminal) described above with an embodiment/example, for example by means of any of FIGS. 2 to 7, comprises not only prior art means, but also means for implementing the one or more functions/operations of a corresponding functionality described with an embodiment, for example by means of any of FIGS. 2 to 7, and it may comprise separate means for each separate function/operation, or means may be configured to perform two or more functions/operations. For example, one or more of the means and/or the local encoder controlling unit, or its sub-units, and/or the local decoder controlling unit, or its sub-units, described above may be implemented in hardware (one or more devices), firmware (one or more devices), software (one or more modules), or combinations thereof. For a hardware implementation, the apparatus(es) of embodiments may be implemented within one or more application-specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, logic gates, decoder circuitries, encoder circuitries, other electronic units designed to perform the functions described herein by means of FIGS. 1A to 7, or a combination thereof. For firmware or software, the implementation can be carried out through modules of at least one chipset (e.g. procedures, functions, and so on) that perform the functions described herein. The software codes may be stored in a memory unit and executed by processors. The memory unit may be implemented within the processor or externally to the processor. In the latter case, it can be communicatively coupled to the processor via various means, as is known in the art. Additionally, the components described herein may be rearranged and/or complemented by additional components in order to facilitate the achievements of the various aspects, etc., described with regard thereto, and they are not limited to the precise configurations set forth in the given figures, as will be appreciated by one skilled in the art.

FIG. 8 provides an apparatus (device) according to some embodiments of the invention. FIG. 8 illustrates an apparatus configured to carry out at least the functions described above in connection with decoding, preferably also with encoding. Each apparatus may comprise one or more communication control circuitry, such as at least one processor 802, and at least one memory 804, including one or more algorithms 803, such as a computer program code (software) wherein the at least one memory and the computer program code (software) are configured, with the at least one processor, to cause the apparatus to carry out any one of the exemplified functionalities of the device described above.

Referring to FIG. 8, at least one of the communication control circuitries in the apparatus 800 is configured to provide the local encoder controlling unit, or its subunits, and/or the local decoder controlling unit, or its sub-units, and/or their combinations, and to carry out functionalities described above by means of any of FIGS. 3 to 7 by one or more circuitries.

Referring to FIG. 8, the memory 804 may be implemented using any suitable data storage technology, such as semiconductor based memory devices, flash memory, magnetic memory devices and systems, optical memory devices and systems, fixed memory and removable memory.

Referring to FIG. 8, the apparatus may further comprise different interfaces 801 such as one or more communication interfaces (TX/RX) comprising hardware and/or software for realizing communication connectivity over the medium according to one or more communication protocols. The communication interface may provide the apparatus with communication capabilities to communicate in the cellular communication system and enable communication between terminal devices and different network nodes and/or a communication interface to enable communication between different network nodes, for example. The communication interface may comprise standard well-known components such as an amplifier, filter, frequency-converter, (de)modulator, and encoder/decoder circuitries, controlled by the corresponding controlling units, and one or more antennas. The communication interfaces may comprise radio interface components providing the device with radio communication capability in a cell. The communication interfaces may comprise optical interface components providing the device with optical fibre communication capability.

As used in this application, the term ‘circuitry’ may refer to one or more or all of the following: (a) hardware-only circuit implementations, such as implementations in only analog and/or digital circuitry, and (b) combinations of hardware circuits and software (and/or firmware), such as (as applicable): (i) a combination of analog and/or digital hardware circuit(s) with software/firmware and (ii) any portions of hardware processor(s) with software, including digital signal processor(s), software, and memory(ies) that work together to cause an apparatus, such as a mobile device or a network device or a server, to perform various functions, and (c) hardware circuit(s) and processor(s), such as a microprocessor(s) or a portion of a microprocessor(s), that requires software (e.g. firmware) for operation, but the software may not be present when it is not needed for operation. This definition of ‘circuitry’ applies to all uses of this term in this application, including any claims. As a further example, as used in this application, the term ‘circuitry’ also covers an implementation of merely a hardware circuit or processor (or multiple processors) or a portion of a hardware circuit or processor and its (or their) accompanying software and/or firmware. The term ‘circuitry’ also covers, for example and if applicable to the particular claim element, a baseband integrated circuit for a mobile device or a similar integrated circuit in a server, a cellular network device, or other computing or network device.

In embodiments, the at least one processor, the memory, and the computer program code form processing means or comprises one or more computer program code portions for carrying out one or more operations according to any one of the embodiments of FIGS. 2 to 7 or operations thereof.

Embodiments as described may also be carried out in the form of a computer process defined by a computer program or portions thereof. Embodiments of the methods described in connection with FIGS. 1A to 7 may be carried out by executing at least one portion of a computer program comprising corresponding instructions. The computer program may be in source code form, object code form, or in some intermediate form, and it may be stored in some sort of carrier, which may be any entity or device capable of carrying the program. For example, the computer program may be stored on a computer program distribution medium readable by a computer or a processor. The computer program medium may be, for example but not limited to, a record medium, computer memory, read-only memory, electrical carrier signal, telecommunications signal, and software distribution package, for example. The computer program medium may be a non-transitory medium. Coding of software for carrying out the embodiments as shown and described is well within the scope of a person of ordinary skill in the art.

Even though the invention has been described above with reference to examples according to the accompanying drawings, it is clear that the invention is not restricted thereto but can be modified in several ways within the scope of the appended claims. Therefore, all words and expressions should be interpreted broadly and they are intended to illustrate, not to restrict, the embodiment. It will be obvious to a person skilled in the art that, as technology advances, the inventive concept can be implemented in various ways. Further, it is clear to a person skilled in the art that the described embodiments may, but are not required to, be combined with other embodiments in various ways.

1-28. (canceled)

29. A method comprising:
receiving, in a device, information to be sent over a medium;
determining, by the device, redundancy information from a set of information symbols at the specific position;
causing, by the device, encoding information symbols at the specific position and the redundancy information, to a spatially coupled chain; and
causing, by the device, sending the information as the spatially coupled chain with the redundancy information as local decision verification codes.

30. A method as claimed in claim 29, further comprising:
determining, by the device, the redundancy information by computing one or more local cyclic redundancy check codes at the specific position;
performing, by the device, cyclic redundancy check encoding to information comprising both the received information and the redundancy information by associating bits in the specific position with corresponding one or more local cyclic redundancy check codes; and
forming the spatially coupled chain by performing to the result of the cyclic redundancy check encoding spatially coupled low density parity check code encoding.

31. A method as claimed in claim 30, wherein the cyclic redundancy check encoding is formed by a round of successive cyclic redundancy check encodings and/or by overlapping cyclic redundancy checks.

32. A method as claimed in claim 29, further comprising:
determining, by the device, one or more design parameters of cyclic redundancy check codes according to at least one of characteristics of a waveform carrying the spatially coupled chain, a shape of the waveform, and expected characteristics of the medium channel;
calculating, by the device, the redundancy information as one or more local cyclic redundancy check codes at the specific position according to the one or more design parameters;
performing, by the device, cyclic redundancy check encoding to information comprising both the received information and the redundancy information by inserting bits in the one or more local cyclic redundancy check codes so that the bits are inserted regularly in the received information; and
causing obtaining, by the device, the spatially coupled chain by spatially coupling the result of the cyclic redundancy check encoding.

33. A method as claimed in claim 32, wherein the spatially coupled chain is obtained by performing spatially coupled low density parity check code encoding, or by spatially coupled turbo code encoding or spatially coupled equalization.

34. An apparatus comprising
at least one processor; and
at least one memory including computer program code;
the at least one memory and the computer program code configured to, with the at least one processor, cause the apparatus at least to perform:
determining redundancy information from a set of information symbols at a specific position of received information that is to be sent over a medium;
encoding or causing encoding information symbols at the specific position and the redundancy information, to a spatially coupled chain; and
causing sending the information as the spatially coupled chain with the redundancy information as local decision verification codes.

35. An apparatus as claimed in claim 34, wherein the at least one memory and the computer program code are configured to, with the at least one processor, further cause the apparatus at least to perform:
determining the redundancy information by computing one or more local cyclic redundancy check codes at the specific position;
performing cyclic redundancy check encoding to information comprising both the received information and the redundancy information by associating bits in the specific position with corresponding one or more local cyclic redundancy check codes; and
forming the spatially coupled chain by performing to the result of the cyclic redundancy check encoding spatially coupled low density parity check code encoding.

36. A device as claimed in claim 35, wherein the cyclic redundancy check encoding is formed by a round of successive cyclic redundancy check encodings and/or by overlapping cyclic redundancy checks.

37. An apparatus as claimed in claim 34, wherein the at least one memory and the computer program code are configured to, with the at least one processor, further cause the apparatus at least to perform:
determining one or more design parameters of cyclic redundancy check codes according to at least one of characteristics of a waveform carrying the spatially coupled chain, a shape of the waveform, and expected characteristics of the medium channel;
calculating the redundancy information as one or more local cyclic redundancy check codes at the specific position according to the one or more design parameters;
performing cyclic redundancy check encoding to information comprising both the received information and the redundancy information by inserting bits in the one or more local cyclic redundancy check codes so that the bits are inserted regularly in the received information; and
causing obtaining, by the device, the spatially coupled chain by spatially coupling the result of the cyclic redundancy check encoding.

38. A device as claimed in claim 37, wherein the spatially coupled chain is obtained by performing spatially coupled low density parity check code encoding, or by spatially coupled turbo code encoding or spatially coupled equalization.

39. A non-transitory computer readable medium comprising program instructions for causing an apparatus to perform at least the following:
determining redundancy information from a set of information symbols at a specific position of received information that is to be sent over a medium;
encoding or causing encoding information symbols at the specific position and the redundancy information, to a spatially coupled chain; and
causing sending the information as the spatially coupled chain with the redundancy information as local decision verification codes.

40. A non-transitory computer readable medium as claimed in claim 39, further comprising:
determining, by the device, the redundancy information by computing one or more local cyclic redundancy check codes at the specific position;
performing, by the device, cyclic redundancy check encoding to information comprising both the received information and the redundancy information by associating bits in the specific position with corresponding one or more local cyclic redundancy check codes; and
forming the spatially coupled chain by performing to the result of the cyclic redundancy check encoding spatially coupled low density parity check code encoding.

41. A non-transitory computer readable medium as claimed in claim 40, wherein the cyclic redundancy check encoding is formed by a round of successive cyclic redundancy check encodings and/or by overlapping cyclic redundancy checks.

42. A non-transitory computer readable medium as claimed in claim 39, further comprising:
determining, by the device, one or more design parameters of cyclic redundancy check codes according to at least one of characteristics of a waveform carrying the spatially coupled chain, a shape of the waveform, and expected characteristics of the medium channel;
calculating, by the device, the redundancy information as one or more local cyclic redundancy check codes at the specific position according to the one or more design parameters;
performing, by the device, cyclic redundancy check encoding to information comprising both the received information and the redundancy information by inserting bits in the one or more local cyclic redundancy check codes so that the bits are inserted regularly in the received information; and
causing obtaining, by the device, the spatially coupled chain by spatially coupling the result of the cyclic redundancy check encoding.

43. A non-transitory computer readable medium as claimed in claim 42, wherein the spatially coupled chain is obtained by performing spatially coupled low density parity check code encoding, or by spatially coupled turbo code encoding or spatially coupled equalization.
